(19) United States
(12) Patent Application Publication
(10) Pub. No.: US 2011/0073894 A1
(43) Pub. Date: Mar. 31, 2011

(54) LIGHT-EMITTING DIODE AND METHOD FOR MANUFACTURING THE SAME

(75) Inventors: Chang Hsin Chu, Tainan County (TW); Chi Meng Lu, Tainan County (TW); Yu Ju Chang, Tainan County (TW); Kuo Hui Yu, Tainan County (TW)

(73) Assignee: Chi Mei Lighting Technology Corporation, Tainan County (TW)

(21) Appl. No.: 12/955,369

(22) Filed: Nov. 29, 2010

(30) Foreign Application Priority Data
Mar. 11, 2009 (TW) TW098107927

(51) Int. Cl. H01L 33/10; H01L 33/58; H01L 33/44; H01L 33/00

(52) U.S. Cl. 257/98; 438/29; 257/E33.001; 257/E33.068; 257/E33.06

(57) ABSTRACT

In one aspect of the invention, an LED includes a substrate, an n-type semiconductor layer, a light emitting layer, a p-type semiconductor layer and a transparent conductive layer sequentially stacked on the substrate, and p-type and n-type electrodes. The p-type semiconductor layer has a rough surface region and at least one flat surface region. The transparent conductive layer has a rough surface region and a flat surface region corresponding to the rough surface region and the at least one flat surface region of the p-type semiconductor layer, respectively. The p-type electrode is disposed on the flat surface region of the transparent conductive layer. The n-type electrode is electrically couple to the n-type semiconductor layer.

### CROSS-REFERENCE TO RELATED PATENT APPLICATION

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference were individually incorporated by reference.

### FIELD OF THE INVENTION

The present invention relates generally to a light emitting diode (LED), and more particular to an LED that utilizes a structure of flat surface regions formed under n-type and p-type electrodes and rough surface regions formed outside the n-type and p-type electrodes to enhance the wiring boding stability and improve the light extraction efficiency of the LED.

### BACKGROUND OF THE INVENTION

Light emitting diodes (LEDs) have been widespread used for lighting with great brightness. Typically, an LED includes a multilayered structure having a p-type semiconductor, an n-type semiconductor and an active layer sandwiched between the p-type and n-type semiconductors, p-type and n-type electrodes placed on the surfaces of the multilayered structure. In operation, a current is injected into the LED from the p-type and n-electrodes, which spreads into the respective semiconductor layers. Light is generated when the current flows across the active layer because of the recombination of minority carriers at the active layer. Generally, the generated light from the active layer may be reflected to different degrees, thereby degrading the light extraction efficiency. In order to improve the light extraction efficiency, a rough surface is usually formed on the p-type semiconductor, by adjusting epitaxial parameters during the epitaxial growth of the p-type semiconductor layer.

FIG. 6 shows a conventional LED 200. The LED 200 includes a substrate 202 and a n-type semiconductor layer 204, a light emitting layer 206, a p-type semiconductor layer 208, a transparent conductive layer 212 sequentially stacked on the substrate 202, and a p-type electrode 216 disposed on the transparent conductive layer 212 and an n-type electrode 220 disposed on an exposed portion of the n-type semiconductor layer 204. To improve the light extraction efficiency, a rough surface 210 is formed on the p-type semiconductor 208, by adjusting epitaxial parameters during the epitaxial growth of the p-type semiconductor layer. As such, the transparent conductive layer 212 also has a rough surface 214. Additionally, after a light emitting area is defined, the exposed portion of the n-type semiconductor layer 204 also has a rough surface 222 similar to the rough surface 210 of the p-type semiconductor layer 208. As a result, the rough surface profile 210 of the p-type semiconductor layer 208 and the rough surface profile 222 of the exposed portion of the n-type semiconductor layer 204 result in a rough surface 224 in the p-type electrode 216 and a rough surface 226 in the n-type electrode 204, respectively.

As shown in FIG. 6, because the rough surface 210 of the p-type semiconductor layer 208 may result in poor step coverage of the transparent conductive layer 212 during the deposition of the transparent conductive layer 212, the current flow in the transparent conductive layer 212 may be discontinued at some points. This will reduce the current spreading ability of the transparent conductive layer 212 and thus give rise to increase of the operation voltage Vf and non-uniformity of the current density, thereby, affecting the lifetime and the operation stability of the LED. Further, for the deposition of the transparent conductive layer 212 having the rough surface 214 with large depth-to-width ratios of dents, voids 218 may be formed in the transparent conductive layer 212. The presence of the voids 218, which may contain air, chemical remains and/or photoresists, degrades the reliability of the LED. In addition, because of the rough surface profile 224 of the p-type electrode 216, dusts such as wax and chemical remains produced on the rough surface 224 during the manufacture process may not easily be cleaned, which reduces the adhesion of the wire bonding in the packaging, and thus, degrades the reliability and the yield rate of the wire bonding, which in turn, reduce the reliability and the stability of the LED.

Therefore, a heretofore unaddressed need exists in the art to address the aforementioned deficiencies and inadequacies.

### SUMMARY OF THE INVENTION

Accordingly, the objectives of the present invention are to provide novel structures of an LED which overcome the aforementioned problems described above.

One objective of the present invention is to provide an LED having flat surface regions on which a p-type electrode and an n-type electrode are disposed and rough surface regions for improving the stability of the wiring bonding and the light extraction efficiency.

Another objective of the present invention is to provide an LED having a p-type semiconductor layer with at least flat surface region in which p+ doped semiconductors are removed and a transparent conductive layer such that in operation, a current flow vertically from the transparent conductive layer to the at least flat surface region of the p-type semiconductor layer is blocked, thereby, avoiding the current congestion effect under the flat surface region, and increasing the light emitting efficiency of the LED.

Yet another objective of the present invention is to provide an LED having a p-type semiconductor layer with at least flat surface region, a transparent conductive layer and a reflective layer formed between the at least flat surface region of the p-type semiconductor layer and the transparent conductive layer such that in operation, a current flow vertically from the at least flat surface region of the p-type semiconductor layer to the transparent conductive layer is blocked, thereby, avoiding the current congestion effect under the flat surface region, and increasing the light emitting efficient of the LED.

A further another objective of the present invention is to provide methods of manufacturing the above LEDs.

In one aspect, the present invention relates to an LED. In one embodiment, the LED includes a substrate; a first semiconductor layer disposed on the substrate, having a first portion and a second portion extending from each other, wherein the first portion has a rough surface region and a flat surface region recessed relative to the rough surface region; a light emitting layer disposed on the second portion of the first semiconductor layer, defining a light emitting region thereon; a second semiconductor layer disposed on the light emitting layer, having a rough surface region and at least one flat surface region recessed relative to the rough surface region, wherein the first semiconductor layer and the second semiconductor layer have different electrical conductivities; an insulative layer disposed on the at least flat surface region of the second semiconductor layer; a transparent conductive layer disposed on the insulative layer and the rough surface region of the second semiconductor layer such that the transparent conductive layer has a rough surface region and a flat surface region corresponding to the rough surface region and the at least one flat surface region of the second semiconductor layer, respectively; a first electrode disposed on the flat surface region of the first semiconductor layer; and a second electrode disposed on the flat surface region of the transparent conductive layer.

The LED further includes a passivation layer disposed on the rough surface region of the transparent conductive layer and the rough surface region of the first portion of the first semiconductor.

In one embodiment, the first semiconductor layer is formed of an n-type semiconductor, and the second semiconductor layer is formed of a p-type semiconductor. The first electrode is an n-type electrode, and the second electrode is a p-type electrode.

In one embodiment, the insulative layer has a thickness greater than about 5 nm. In another embodiment, the insulative layer has an area greater than the at least one flat surface region of the second semiconductor layer. In yet another embodiment, the insulative layer comprises a multilayer having a reflective characteristic greater than about 50%. The insulative layer is formed of SiO₂, SiN, TiO₂ or Al₂O₃.

In another aspect of the present invention, an LED includes a substrate; a first semiconductor layer disposed on the substrate; a light emitting layer disposed on the first semiconductor layer; a second semiconductor layer disposed on the light emitting layer, having a rough surface region and at least one flat surface region, wherein the first semiconductor layer and the second semiconductor layer have different electrical conductivities; a transparent conductive layer disposed on the second semiconductor layer such that the transparent conductive layer has a rough surface region and a flat surface region corresponding to the rough surface region and the at least one flat surface region of the second semiconductor layer, respectively; a first electrode electrically coupled to the first semiconductor layer; and a second electrode disposed on the flat surface region of the transparent conductive layer. In operation, no current flows vertically from the flat surface region of the transparent conductive layer to the at least one flat surface region of the second semiconductor layer.

In one embodiment, the at least one flat surface region of the second semiconductor layer is recessed relative to the rough surface region of the second semiconductor layer.

In one embodiment, the first semiconductor layer has a first portion and a second portion extending from each other, where the first portion has a rough surface region and a flat surface region. The first electrode disposed on the flat surface region of the first portion of the first semiconductor layer. The light emitting layer disposed on the second portion of the first semiconductor layer so as to define a light emitting region thereon.

In one embodiment, the flat surface region of the first semiconductor layer is recessed relative to the rough surface region of the first semiconductor layer.

The first semiconductor layer is formed of an n-type semiconductor, and the second semiconductor layer is formed of a p-type semiconductor, and wherein the first electrode is an n-type electrode, and the second electrode is a p-type electrode.

In one embodiment, the second semiconductor layer comprises a p-type semiconductor layer formed on the light emitting layer; and a p+ doped semiconductor layer formed on the rough surface region of the p-type semiconductor layer.

In one embodiment, the flat surface region of the transparent conductive layer and the at least one flat surface region of the second semiconductor layer are in a Schottky contact.

The LED further includes a reflective layer formed between the flat surface region of the transparent conductive layer and the at least one flat surface region of the second semiconductor layer. In one embodiment, the reflective layer has an area greater than the at least one flat surface region of the second semiconductor layer. In another embodiment, the reflective layer comprises an insulative layer, a stacked structure of an insulative layer and a metal layer, or a metal layer. In another embodiment, the reflective layer comprises a single layer, or a multilayer.

Additionally, the LED also includes a passivation layer disposed on the rough surface region of the transparent conductive layer and the rough surface region of the first portion of the first semiconductor.

In yet another aspect of the present invention, a method of manufacturing an LED, comprising the steps of providing a substrate; and sequentially forming an n-type semiconductor layer on the substrate, a light emitting layer on the n-type semiconductor layer, and a p-type semiconductor layer on the light emitting layer, wherein the p-type semiconductor layer has a rough surface having a first region, a second region and a third region separated from the second region.

In one embodiment, the p-type semiconductor layer comprises a p-type semiconductor layer formed on the light emitting layer; and a p+ doped semiconductor layer formed on the p-type semiconductor layer. In one embodiment, the p-type semiconductor layer has at least a fourth region extending from the second region, wherein the fourth region is adapted for forming a fourth flat surface region.

Each of the n-type semiconductor layer, the light emitting layer and the p-type semiconductor layer is formed of a GaN based material.

Furthermore, the method includes the steps of forming a first mask layer on the first region of the rough surface of the p-type semiconductor layer, thereby exposing the second and third regions of the rough surface of the p-type semiconductor layer; and forming a second mask layer on the first mask layer and the exposed second and third regions of the rough surface of the p-type semiconductor layer, wherein the second mask layer and the p-type semiconductor layer have a substantially same etching rate, wherein the first mask layer has an etching rate less than that of the second mask layer and the p-type semiconductor layer;

In one embodiment, the first mask layer is formed of SiO₂, SiNx, SiOₓN_{y}, BPSG, spin-on-glass (SOG), or polyimide. In one embodiment, the second mask layer is formed of a photoresist (PR) material. In another embodiment, the second mask layer is formed of a SOG material.

Moreover, the method includes the steps of performing an etching process on the second mask layer and the first mask layer so as to form a first flat surface region and a second flat surface region in the second and third regions of the p-type semiconductor layer, respectively, and to expose the rough surface of the first region of the p-type semiconductor layer; and removing a portion of the p-type semiconductor layer in which the second flat surface region is located and a corresponding portion of the light emitting layer so as to expose a portion of the n-type semiconductor layer, and forming a third flat surface region on the exposed portion of the n-type semiconductor layer. In one embodiment, the third flat surface region on the exposed portion of the n-type semiconductor layer is corresponding to the second flat surface region of the p-type semiconductor layer, and wherein the exposed portion of the n-type semiconductor layer further has a rough surface region extending from the third flat surface region.

In one embodiment, the etching process is performed with a dry etching process, where the dry etching process comprises an inductively coupled plasma (ICP) process, or a reactive ion etch (RIE) process. In one embodiment, the etching process further comprises removing the p+ doped semiconductor layer in the second and third regions of the p-type semiconductor layer.

Additionally, the method also includes the steps of forming a transparent conductive layer on the rough surface region and the first flat surface region of the p-type semiconductor layer, such that the transparent conductive layer has a rough surface region and a flat surface region corresponding to the rough surface region and the first flat surface region of the p-type semiconductor layer, respectively; and forming an n-type electrode on the third flat surface region of the n-type semiconductor layer and a p-type electrode on the flat surface region of transparent conductive layer.

In one embodiment, the flat surface region of transparent conductive layer and the first flat surface region of the second semiconductor layer are in a Schottky contact.

In one embodiment, the method also includes the step of forming a reflective layer between the flat surface region of the transparent conduct layer and the first flat surface region of the p-type semiconductor layer.

The method may also includes the step of forming a passivation layer on the rough surface region of the exposed portion of the n-type semiconductor layer and the rough surface region of the transparent conductive layer, after forming the n-type electrode and the p-type electrode.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIGS. 1A-1E show schematically a cross-sectional view of an LED and its manufacturing process according to one embodiment of the present invention;

FIGS. 2A-2D show schematically a cross-sectional view of an LED and its manufacturing process according to another embodiment of the present invention;

FIG. 3 shows schematically a cross-sectional view of an LED according to yet another embodiment of the present invention;

FIGS. 4A and 4B show schematically a top view and a cross-sectional view, respectfully, of an LED according to an alternative embodiment of the present invention;

FIG. 5 shows schematically a cross-sectional view of an LED according to a further embodiment of the present invention; and

FIG. 6 shows schematically a cross-sectional view of a conventional LED.

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The term “layer”, as used herein, refers to a thin sheet or thin film.

The term “electrode”, as used herein, is an electrically conductive layer or film formed of one or more electrically conductive materials.

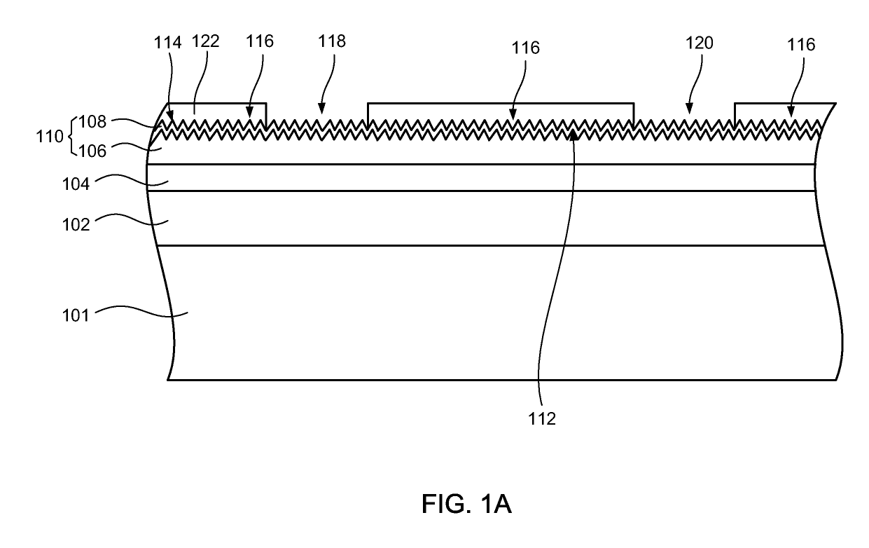

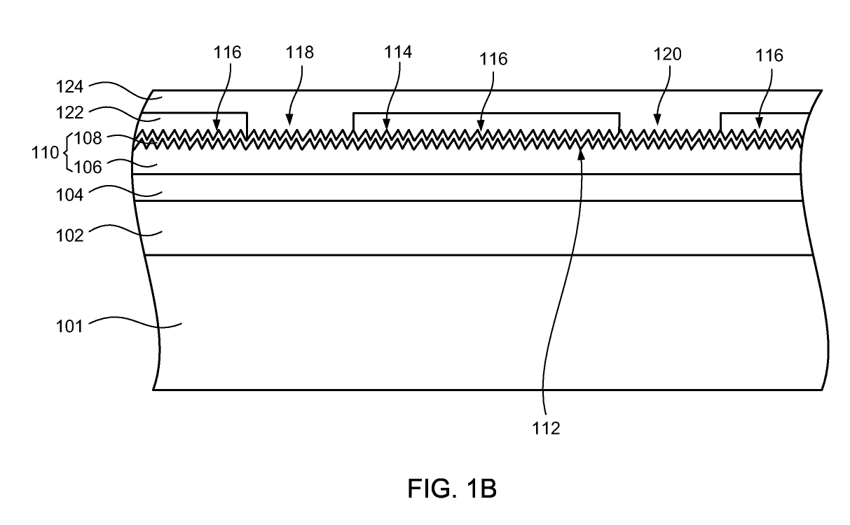

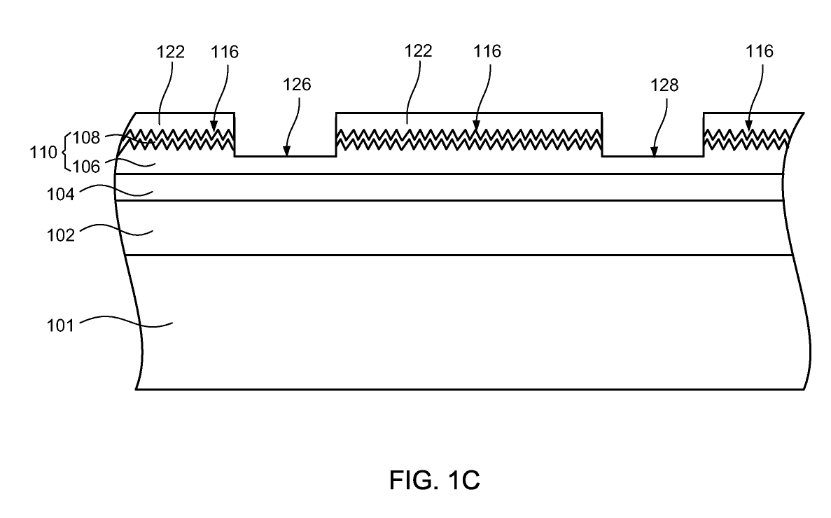

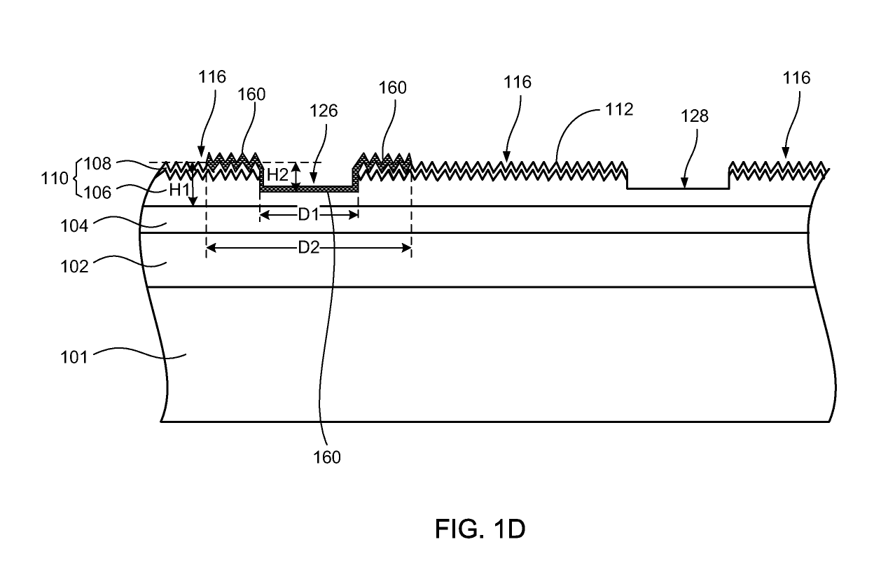

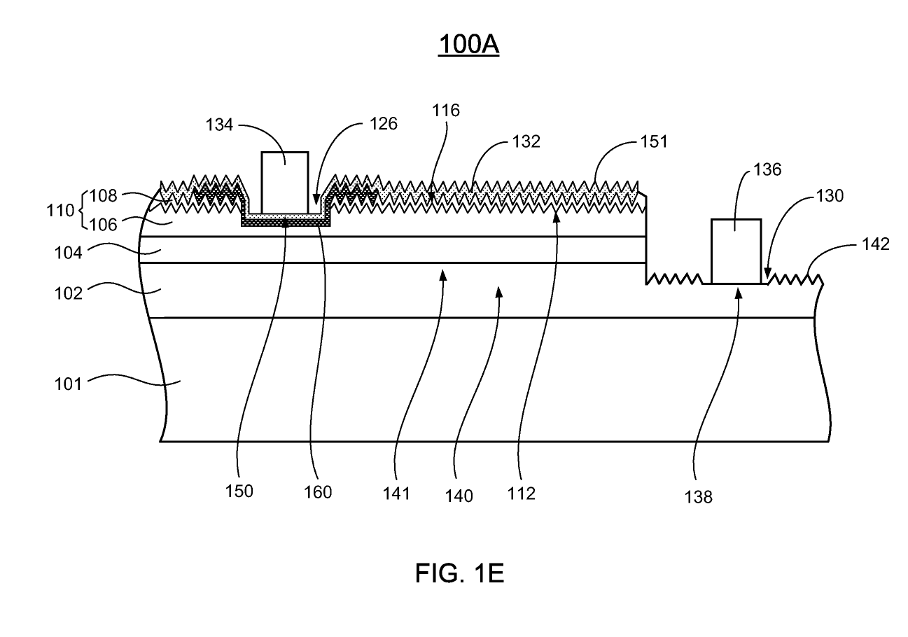

The description will be made as to the embodiments of the present invention in conjunction with the accompanying drawings of FIGS. 1-5. In accordance with the purposes of this invention, as embodied and broadly described herein, this invention, in one aspect, relates to an LED and method of manufacturing same.

Referring to FIGS. 1A-1E, an LED 100A and its manufacturing process are schematically shown according to one embodiment of the present invention. As shown in FIG. 1E, the LED 100A includes a substrate 101, a first semiconductor layer 102 disposed on the substrate 101. The first semiconductor layer 102 has a first portion 138 and a second portion 140 extending from each other, where the first portion 138 has a rough surface region 142 and a flat surface region 130 recessed relative to the rough surface region 142.

The LED 100A further includes a light emitting layer 104 disposed on the second portion 140 of the first semiconductor layer 102, defining a light emitting region 141 thereon, and a second semiconductor layer 110 disposed on the light emitting layer 104. The second semiconductor layer 110 has a rough surface region 112 and a flat surface region 126. The flat surface region 126 is recessed relative to the rough surface region 112 to define a depth, H2, and has a dimension, D1, for example, a diameter. The depth H2 of the flat surface region 126 is less than a thickness, H1, of the second semiconductor layer 106, as shown in FIG. 1D. In one embodiment, additional flat surface regions may be defined in the second semiconductor layer 106.

The first semiconductor layer 102 and the second semiconductor layer 110 have different electrical conductivities. For example, the first semiconductor layer 102 comprises an n-type semiconductor, while the second semiconductor layer 110 comprises a p-type semiconductor 106. Further, the second semiconductor layer 110 has a p+ doped semiconductor layer 108 is formed on the rough surface region 112 of the p-type semiconductor layer 106, so that the p+ doped semiconductor layer 108 also has a rough surface 114 as well.

Additionally, the LED 100A also includes an insulative layer 160 disposed on the flat surface region 126 of the second semiconductor layer 106. The insulative layer 160 is adapted for blocking an injected current flow vertically from the p-type electrode 134 to the flat surface region 126 of the second semiconductor layer 110. In this exemplary embodiment, the insulative layer 160 has an area greater than the flat surface region 126 of the second semiconductor layer 106. As shown in FIG. 1D, for example, the insulative layer 160 is characterized with a dimension or diameter, D2, which is larger than the dimension D1 of the flat surface region 126 of the second semiconductor layer 106. In one embodiment, the insulative layer 160 has a thickness greater than about 5 nm. The insulative layer 160 may be formed of SiO₂, SiN, TiO₂, Al₂O₃, or the likes. In one embodiment, the insulative layer 160 is formed in a multilayer having a reflective characteristic greater than about 50%.

Furthermore, the LED 100A includes a transparent conductive layer 132 disposed on the insulative layer 160 and the rough surface region 112 of the second semiconductor layer 110. According to the present invention, the transparent conductive layer 132 also has a rough surface region 151 and a flat surface region 150 that are corresponding to the rough surface region 112 and the flat surface region 126 of the second semiconductor layer 110, respectively.

The LED 100A has an n-type electrode 136 formed on the flat surface region 130 of the first semiconductor layer 102, and a p-type electrode 134 formed on the flat surface region 150 of the transparent conductive layer 132.

The LED 100A may also include a passivation layer (not shown), selectively disposed on the rough surface region 151 of the transparent conductive layer 132 and the rough surface region 142 of the first portion 138 of the first semiconductor 102.

In one embodiment, the LED 100A can be manufactured according to the processes shown in FIGS. 1A-1D. First, the substrate 101 is provided. An epitaxial growth process is then applied on the substrate 101 to sequentially form the n-type semiconductor layer 102 on the substrate 101, the light emitting layer 104 on the n-type semiconductor layer 102, and the p-type semiconductor layer 106 on the light emitting layer 104 and the p+ doped semiconductor layer 108 on the p-type semiconductor layer 106. By adjusting epitaxial parameters during the epitaxial growth of the p-type semiconductor layer 106, a rough surface 112 can be formed thereon. Accordingly, the p+ doped semiconductor layer 108 also has a rough surface 114. The rough surface 112 can improve the efficiency of the light extraction of the LED 100A. The rough surface 112 defines a first region 116, a second region 118 and a third region 120 separated from the second region 118. The n-type semiconductor layer, the light emitting layer and the p-type semiconductor layer can be formed of GaN based materials, or the likes.

After the growth of the epitaxial structure, a first mask layer 122 is formed on the rough surface 112 of the p-type semiconductor layer 106, for example, by a chemical vapor deposition (CVD), a physical vapor deposition (PVD) or a spin-on coating process. Then, a pattern definition process such as photolithography and/or etching is applied to the first mask layer 122 to remove portions of the first mask layer 122 from the second region 118 and a third region 120 of the rough surface 112 of the p-type semiconductor layer 106, so as to expose the second region 118 and a third region 120 of the rough surface 112 of the p-type semiconductor layer 106, as shown in FIG. 1A. Next, a second mask layer 124 is formed on the first mask layer 122 and the exposed second and third regions 118 and 120 of the rough surface 112 of the p-type semiconductor layer 106, as shown in FIG. 1B.

According to the present invention, the second mask layer 124 and the p-type semiconductor layer 106 have a substantially same etching rate, while the first mask layer 122 has an etching rate less than that of the second mask layer 124 and the p-type semiconductor layer 106. The first mask layer 122 can be formed of SiO₂, SiNx, SiOₓN_{y}, BPSG, SOG, polyimide, or the likes. The first mask layer 122 has a thickness in a range of about 10-1000 nm. The second mask layer 124 is formed of a material of high viscosity such as a photoresist (PR) material, or an SOG material.

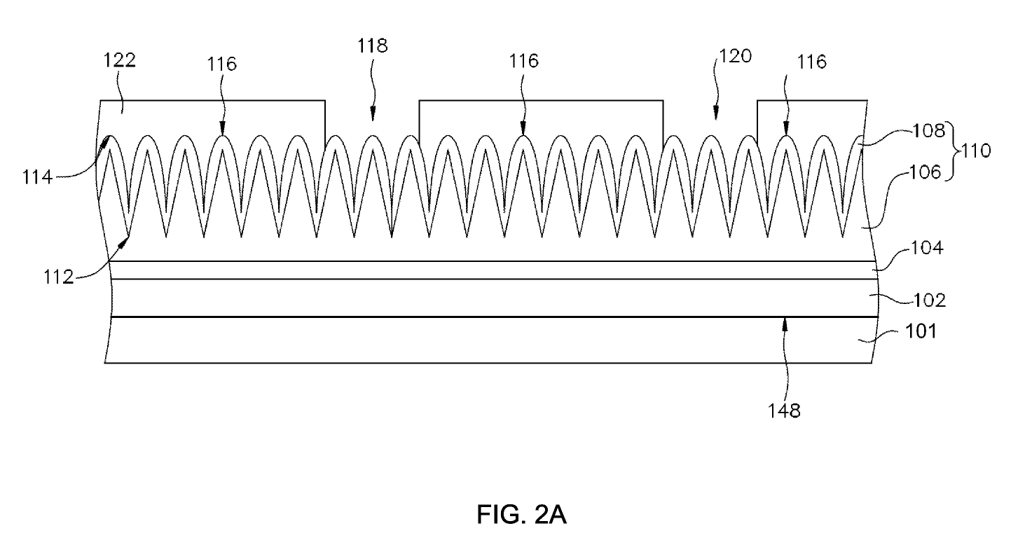

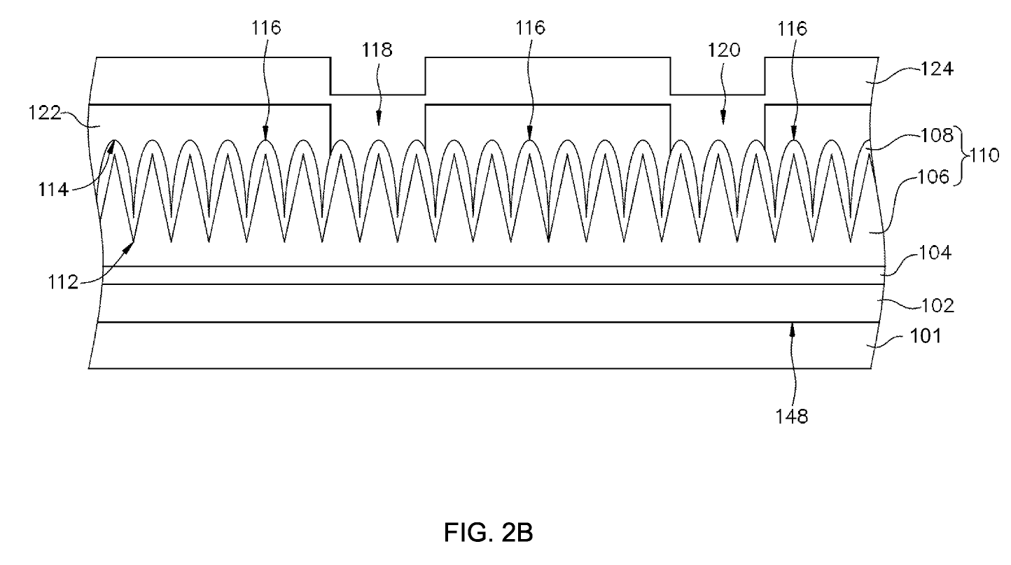

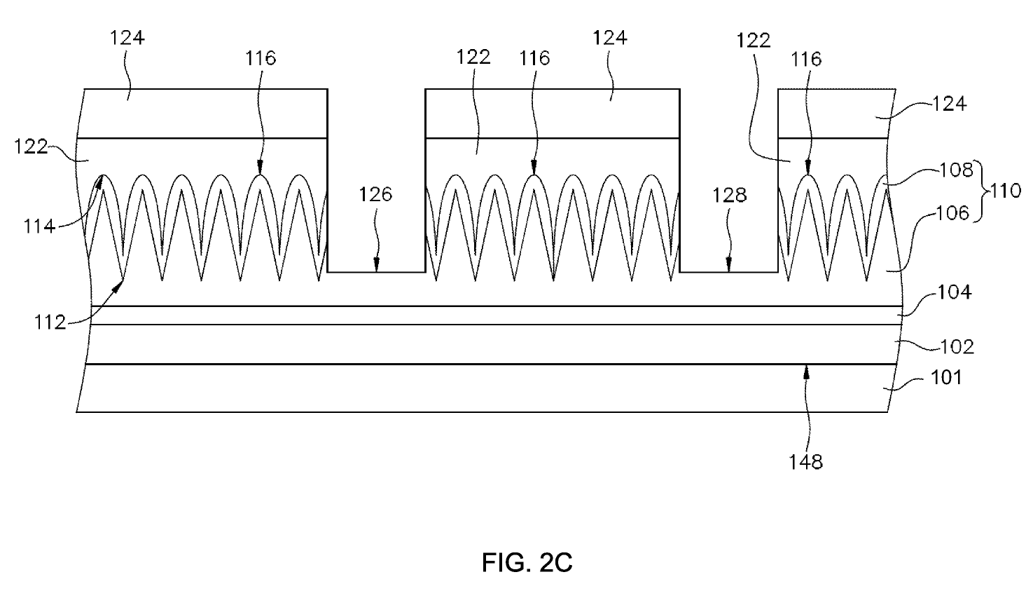

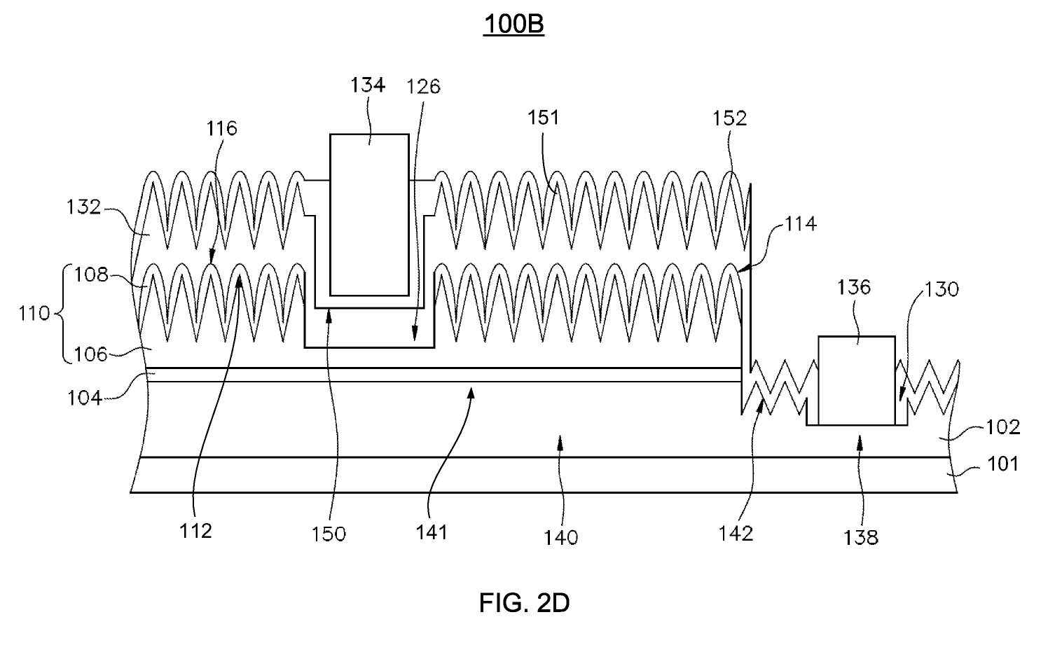

The next step is to form the flat surface regions 126 and 128 in the p-type semiconductor layer 106, by, for example, an etching process. Since the materials of the second mask layer 124 and the p-type semiconductor layer 106 are selected to have etching rates that are same or substantially similar, and the material of the first mask layer 122 has an etching rate less than that of the second mask layer 124 and the p-type semiconductor layer 106, the etching process results in the formation of the first and second flat surface regions 126 and 128 in the second and third regions 118 and 120 of the p-type semiconductor layer 106, respectively, as shown in FIG. 2C. In one embodiment, the etching process is performed with a dry etching process. The dry etching process can be an inductively coupled plasma (ICP) process, or a reactive ion etch (RIE) process. After the etching process, the first and second mask layers 122 and 124 are removed, thereby, exposing the rough surface region 112 of the first region 116 of the p-type semiconductor layer 106, as shown in FIG. 1D.

The insulative layer 160 is then formed on the first flat surface region 126 of the second semiconductor layer 106, as shown in FIG. 1D.

Consequently, the pattern definition process such as photolithography and/or etching is applied to remove a portion of the second semiconductor layer 110, for example, the portion in which the second flat surface region 128 is located, and a corresponding portion of the light emitting layer 104 so as to expose the first portion 138 of the n-type semiconductor layer 102. The remaining light emitting layer 104 and the remaining p-type semiconductor layer 106 are located over the second portion 140 of the n-type semiconductor layer 102, which constitute the light emitting area 141. After the light emitting area 141 is defined, the surface profile of the rough surface region 112 of the p-type semiconductor layer 106 is transferred to the exposed portion 138 of the n-type semiconductor layer 102. Therefore, the exposed portion 138 of the n-type semiconductor layer 102 has a flat surface region 130 and a rough surface region 142, which are corresponding to the second flat surface region 128 of the second semiconductor layer 110 and the rough surface region 112 of the p-type semiconductor layer 106, respectively. In this embodiment, the flat surface region 130 is recessed relative to the rough surface region 142 of the n-type semiconductor layer 102.

Then, the transparent conductive layer 132 is formed on the rough surface region 112 and the first flat surface region 126 of the p-type semiconductor layer 106, by a vapor deposition method such as CVD, or PVD. The transparent conductive layer 132 has a rough surface region 151 and a flat surface region 150 corresponding to the rough surface region 112 and the first flat surface region 126 of the p-type semiconductor layer 106, respectively. The transparent conductive layer 132 is formed of a transparent conductive material, for example, ITO.

The n-type electrode 136 and the p-type electrode 134 are formed on the flat surface region 130 of the n-type semiconductor layer 102 and the flat surface region 150 of transparent conductive layer 132, respectively, for example, by a vapor deposition method such as CVD, or PVD.

Referring to FIGS. 2A-2D, an LED 100B and its manufacturing process are schematically shown according to another embodiment of the present invention. The LED 100B is structurally similar to the LED 100A shown in FIG. 1E, except that the LED 100B do not have an insulative layer 160. As shown in FIG. 2D, the LED 100B includes a substrate 101, a first semiconductor layer 102, a light emitting layer 104, a second semiconductor layer 110, a transparent conductive layer 132 and a passivation layer 152 sequentially stacked together. The first semiconductor layer 102 and the second semiconductor layer 110 have different electrical conductivities. For example, the first semiconductor layer 102 comprises an n-type semiconductor, while the second semiconductor layer 110 comprises a p-type semiconductor.

Specifically, the first semiconductor layer 102 is disposed on the substrate 101, having a first portion 138 and a second portion 140 extending from each other. The first portion 138 has a rough surface region 142 and a flat surface region 130 recessed relative to the rough surface region 142.

The light emitting layer 104 is disposed on the second portion 140 of the first semiconductor layer 102, defining a light emitting region thereon 141, which is over the second portion 140 of the first semiconductor layer 102.

The second semiconductor layer 110 has a p-type semiconductor layer 106 disposed on the light emitting layer 104. The p-type semiconductor layer 106 has a rough surface region 112 and a flat surface region 126 recessed relative to the rough surface region 112. Further, the second semiconductor layer 110 has a p+ doped semiconductor layer 108 is formed on the rough surface region 112 of the p-type semiconductor layer 106, so that the p+ doped semiconductor layer 108 also has a rough surface 114 as well.

The transparent conductive layer 132 is disposed on the rough surface region 114 of the p+ doped semiconductor layer 108 and the flat surface region 126 of the p-type semiconductor layer 106 such that the transparent conductive layer 132 has a rough surface region 151 and a flat surface region 126 corresponding to the rough surface region 114 and the flat surface region 126 of the second semiconductor layer 110, respectively.

Further, an n-type electrode 136 is disposed on the flat surface region 130 of the first semiconductor layer 102, and a p-type electrode is disposed on the flat surface region 150 of the transparent conductive layer 132.

The passivation layer 152 is disposed on the rough surface region 151 of the transparent conductive layer 132.

As shown in FIG. 2A, to manufacture such an LED 100B, the substrate 101 is provided. Then, an epitaxial growth process is applied on the surface 148 of the substrate 101 to sequentially form the n-type semiconductor layer 102 on the substrate 101, the light emitting layer 104 on the n-type semiconductor layer 102, and the p-type semiconductor layer 106 on the light emitting layer 104, and the p+ doped semiconductor layer 108 on the p-type semiconductor layer 106. In this exemplary embodiment, the second semiconductor layer 110 has two layers of the p-type semiconductor layer 106 and the p+ doped semiconductor layer 108. The n-type semiconductor layer, the light emitting layer and the p-type semiconductor layer can be formed of GaN based materials, or the likes.

In order to improve the efficiency of the light extraction, the p-type semiconductor layer 106 is formed to have a rough surface 112. This can be implemented, for example, adjusting epitaxial parameters during the epitaxial growth of the p-type semiconductor layer 106. Accordingly, the p+ doped semiconductor layer 108 also has a rough surface 114. The rough surface 112 and thus the rough surface 114 defines a first region 116, a second region 118 and a third region 120 separated from the second region 118.

Further, a first mask layer 122 is formed on the rough surface 114 of the second semiconductor layer 110, for example, by a CVD, a PVD or a spin-on coating process. Then, pattern definition processes such as photolithography and etching are applied to the first mask layer 122 to remove portions of the first mask layer 122 from the second region 118 and a third region 120 of the rough surface 114 of the second semiconductor layer 110, so as to expose the second region 118 and a third region 120 of the rough surface 114 of the second semiconductor layer 110. The first mask layer can be formed of SiO₂, SiNx, SiOₓN_{y}, BPSG, SOG, polyimide, or the likes.

As shown in FIG. 2B, the next step is using a spin coating process to form a second mask layer 124 on the first mask layer 122 and the exposed second and third regions 118 and 120 of the rough surface 114 of the second semiconductor layer 110. As a result, the surfaces of the second mask layer 124 over the second and third regions 118 and 120 are flat.

According to the present invention, the second mask layer 124 and the second semiconductor layer 110 have a substantially same etching rate, while the first mask layer 122 has an etching rate less than that of the second mask layer 124 and the second semiconductor layer 110. In one embodiment, the second mask layer 124 is formed of a material of high viscosity such as a PR material, or an SOG material.

Afterwards, an etching process is performed on the second mask layer 124 and the second and third regions 118 and 120 of the second semiconductor layer 110. Since the materials of the second mask layer 124 and the second semiconductor layer 110 are selected to have etching rates that are same or substantially similar, and the material of the first mask layer 122 has an etching rate less than that of the second mask layer 124 and the second semiconductor layer 110, and further, the surfaces of the second mask layer 124 over the second and third regions 118 and 120 are flat, in the etching process the etching rates of the second mask layer 124 and the second semiconductor layer 110 are same or substantially close, therefore, the flat profiles of the second mask layer 124 over the second and third regions 118 and 120 can be transferred to the second semiconductor layer 110, so that the first and second flat surface regions 126 and 128 are formed in the second and third regions 118 and 120 of the second semiconductor layer 110, respectively, as shown in FIG. 2C. The flat surface region 126 is adapted for the p-type electrode 134, and thus called an electrode region. In one embodiment, the etching process is performed with a dry etching process. The dry etching process can be an ICP process, or an RIE process.

In one embodiment, the etching process also includes removing the p+ doped semiconductor layer 108 from the second and third regions 118 and 120 of the second semiconductor layer 110, which are adapted for current blocking. Accordingly, the p+doped semiconductor layer 108 exists only in the first region 116 of the second semiconductor layer 110. After the etching process, the first and second mask layers 122 and 124 are removed, thereby, exposing the rough surface region 114 of the first region 116 of the second semiconductor layer 110.

Next steps include defining the light emitting area 141 and forming the transparent conductive layer 132, as shown in FIG. 2D. The order of performing the two steps is in accordance with the need of the manufacture process. In one embodiment, the light emitting area 141 is defined first, which uses the pattern definition process such as photolithography and/or etching are applied to remove a portion of the second semiconductor layer 110, for example, the portion in which the second flat surface region 128 is located, and a corresponding portion of the light emitting layer 104 so as to expose the first portion 138 of the n-type semiconductor layer 102. The remaining light emitting layer 104 and the remaining second semiconductor layer 110 are located over the second portion 140 of the n-type semiconductor layer 102, constituting the light emitting area 141. After defining the light emitting area 141, the surface profile of the rough surface region 114 of the second semiconductor layer 110 is transferred to the exposed portion 138 of the first semiconductor layer 102. Therefore, the exposed portion 138 of the first semiconductor layer 102 has a flat surface region 130 and a rough surface region 142, which are corresponding to the second flat surface region 128 of the second semiconductor layer 110 and the rough surface region 114 of the second semiconductor layer 110, respectively. The flat surface region 130 is adapted for the n-type electrode 136, and thus called an electrode region. In this embodiment, the flat surface region 130 is recessed relative to the rough surface region 142 of the first semiconductor layer 102. Similarly, the flat surface region 126 is recessed relative to the rough surface region 114 of the second semiconductor layer 110.

Then, the transparent conductive layer 132 is formed on the rough surface region 114 and the first flat surface region 126 of the second semiconductor layer 110, by a vapor deposition method such as CVD, or PVD. The transparent conductive layer 132 has a rough surface region 151 and a flat surface region 150 corresponding to the rough surface region 114 and the first flat surface region 126 of the second semiconductor layer 110, respectively. The transparent conductive layer 132 is formed of a transparent conductive material, for example, ITO.

The n-type electrode 136 and the p-type electrode 134 are formed on the flat surface region 130 of the n-type semiconductor layer 102 and the flat surface region 150 of transparent conductive layer 132, respectively, for example, by a vapor deposition method such as CVD, or PVD.

The passivation layer 152 is then selectively formed on the rough surface region 151 of the transparent conductive layer 132, and optionally on the rough surface region 142 of the exposed portion 138 of the n-type semiconductor layer 102.

According to the processes as set forth above, the p+ doped semiconductor 108 under the p-type electrode 134 is removed. Therefore, the flat surface region 150 of transparent conductive layer 132 and the first flat surface region 126 of the second semiconductor layer 110 are in a Schottky contact having a Schottky barrier which blocks a current injected from the p-type electrode 134 flowing from the transparent conductive layer 132 under the p-type electrode 134 to the first flat surface region 126 of the second semiconductor layer 110, thereby, forcing the injected current spreading laterally along the flat surface region 150 of transparent conductive layer 132, improving the current distribution and the efficiency of the light emitting of the LED 100B.

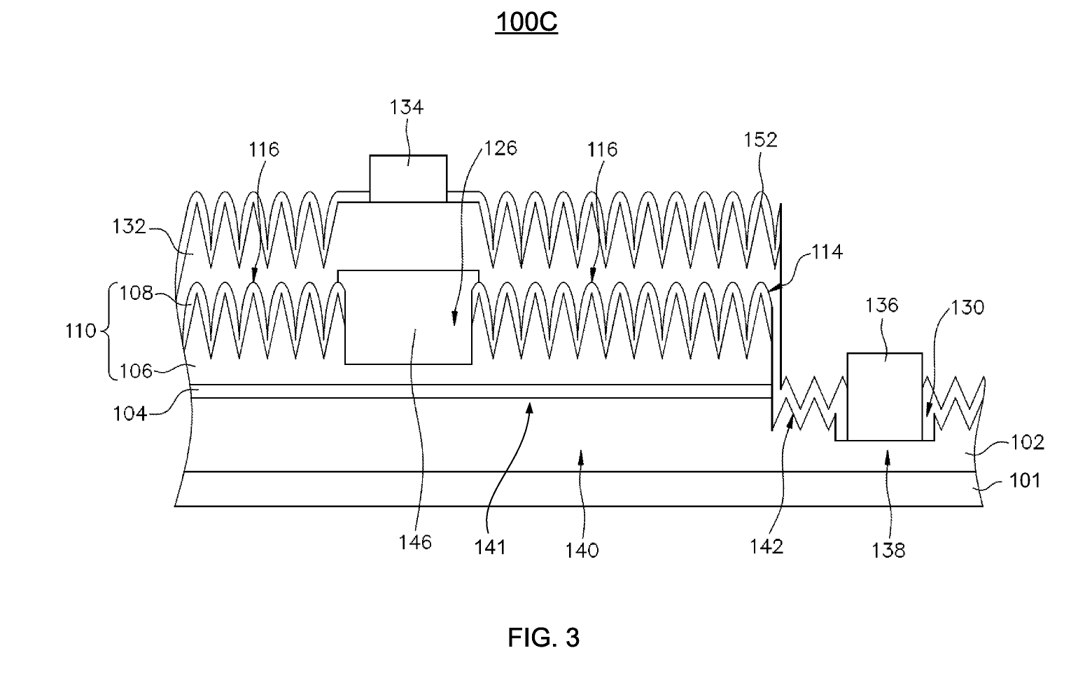

Referring to FIG. 3, a further embodiment of an LED 100C is schematically shown according to the present invention. The LED 100C is structurally similar to the LED 100B of FIG. 2D, except that the LED 100C includes a reflective layer 146 formed between the transparent conduct layer 132 and the first flat surface region 126 of the second semiconductor layer 110. The reflective layer 146 is formed after the light emitting area 141 is defined, but before the transparent conductive layer 132 is formed.

The reflective layer 146 can be formed in a single layer, or a multilayer. The reflective layer 146 includes an insulative layer, a stacked structure of an insulative layer and a metal layer, or a metal layer. The metal layer is formed of high reflective metal material such as, but not limited to, aluminum, silver, platinum, etc. The insulative layer is formed of, but not limited to, SiO₂, SiN, TiO₂ or Al₂O₃, etc. Additionally, the reflective layer 146 can be a distributed Bragg reflector (DBR) formed in a stack of multiple insulative layers.

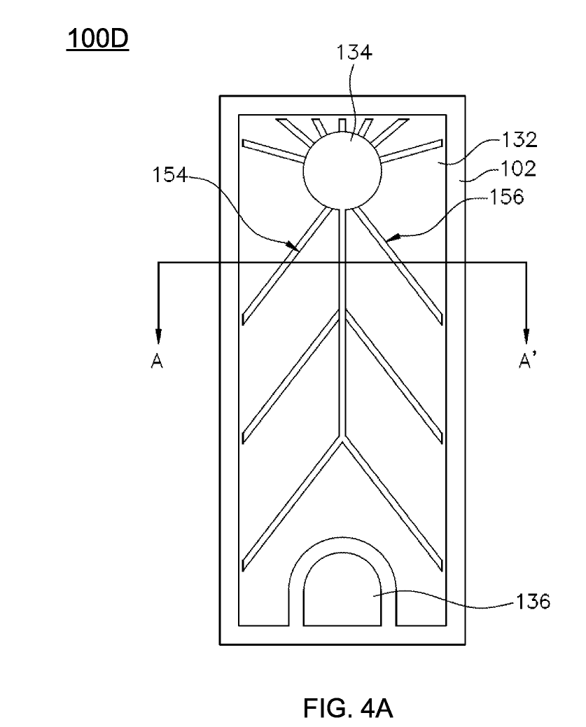

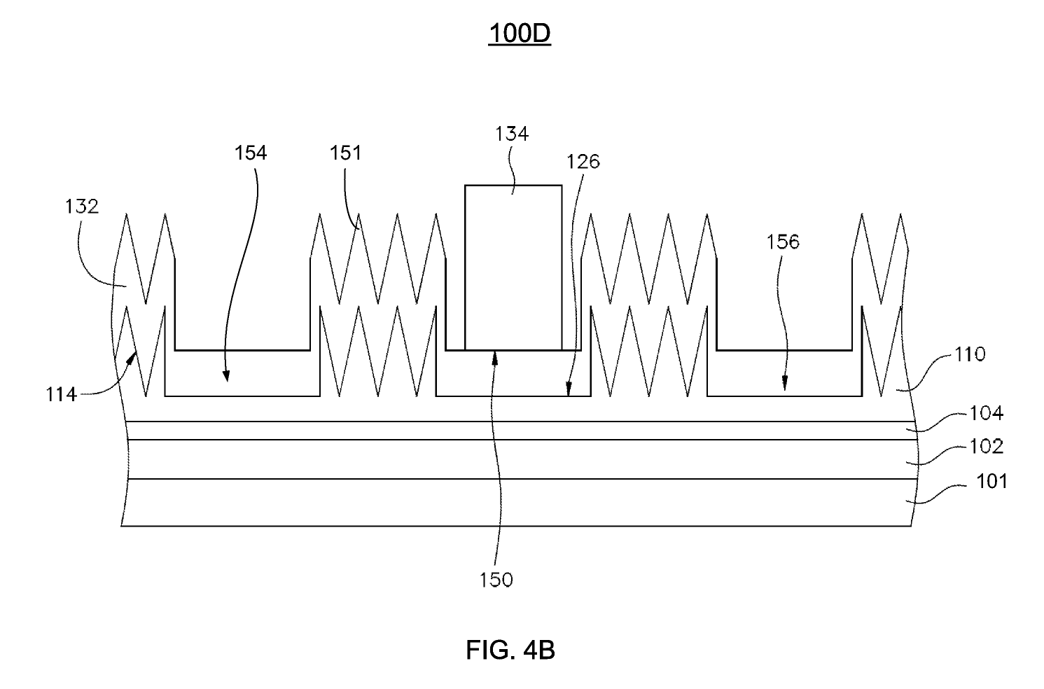

Referring to FIGS. 4A and 4B, an LED 100D is schematically shown according to yet a further embodiment of the present invention. The LED 100D is structurally similar to the LED 100B of FIG. 2D, except that in the LED 100D, the surface 114 of the second semiconductor layer 110 includes additional flat surface regions 154 and 156 extending from the p-type electrode 134, as shown in FIG. 4A.

The manufacturing processes of the LED 100D is similar to that of LED 100B as shown in FIGS. 2A-2D, except that when forming the first mask layer 122, additional desired regions of the surface 114 of the second semiconductor layer 110 are also exposed. Following the processes described above, these additional desired regions are formed into additional flat surface regions, such as flat surface regions 154 and 156 of the second semiconductor layer 110, as shown in FIG. 4B. The thickness of the transparent conductive layer 132 is uniform over the flat surface regions 154 and 156 of the second semiconductor layer 110. Comparing to the rough surface region 151, the transparent conductive layer 132 over the additional flat surface regions 154 and 156 has relative low resistance, and is used for paths of uniform current spreading. This enhances the current spreading ability of the LED 100D, thereby, increasing the light emitting efficiency of the LED 100D.

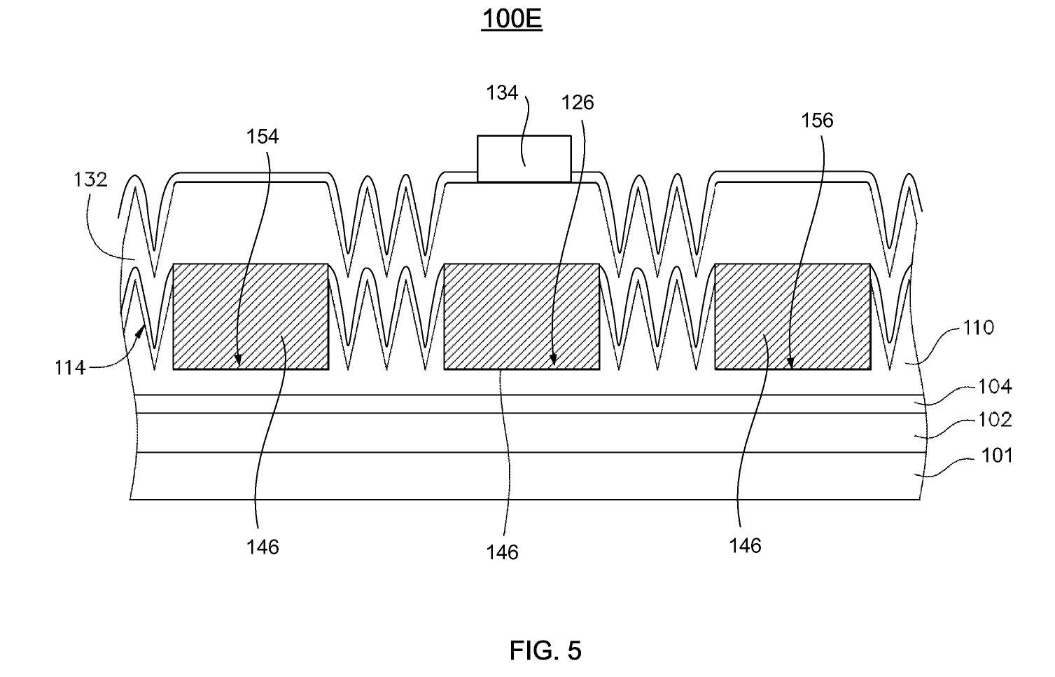

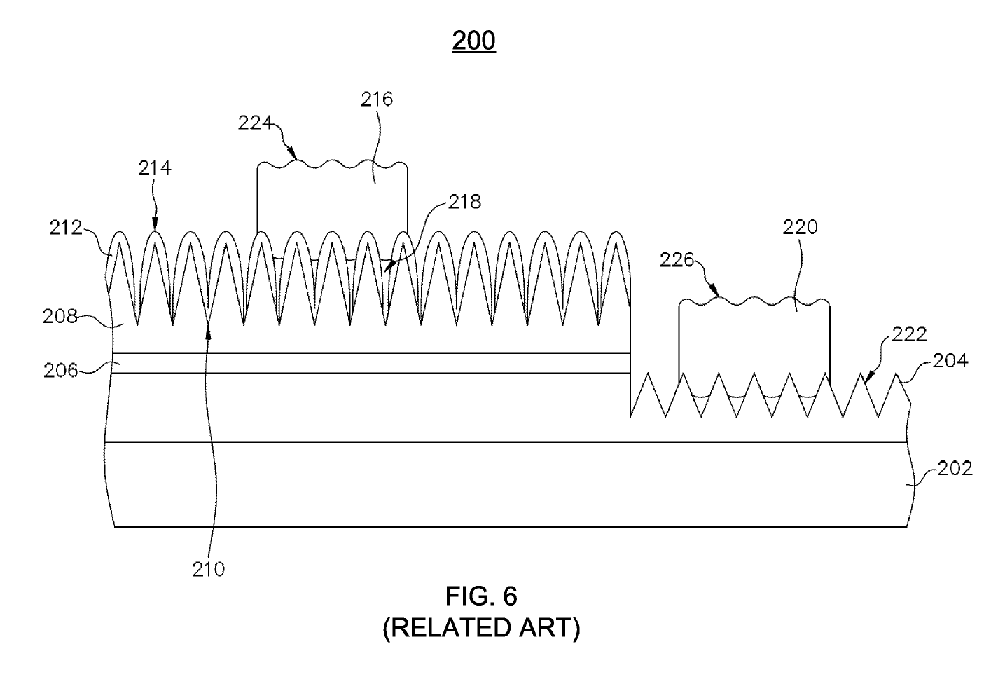

In one embodiment, the p-type electrode 134 may be selectively extended to the transparent conductive layer 132 over the additional flat surface regions 154 and 156 of the second semiconductor layer 110, so as to further increase the uniformity of the current distribution. Furthermore, the reflective layer 146 and/or the insulative layer 160 may be selectively formed between the transparent conductive layer 132 and the additional flat surface regions 154 and 156 of the second semiconductor layer 110, as shown in FIG. 5 of an LED 100E according to one embodiment of the present invention.

The present invention recites an LED and method of manufacturing same, which, among other things, has a great deal of advantages. For example, the structures of the flat surface regions formed under the n-type and p-type electrodes and the rough surface regions formed outside the n-type and p-type electrodes not only enhance the wiring boding stability but improve the light extraction efficiency of the LED.

Additionally, the n-type and p-type electrodes disposed on the flat surface regions also have flat surfaces, which could reduce the color shading of the n-type and p-type electrodes, and improve the accuracy of the electrode identification of packaging equipments, thereby, improving the accuracy of wire bonding positions.

Further, according to the present invention, the LED has a p-type semiconductor layer with the flat surface regions in which p+ doped semiconductors are removed, which provides a barrier, such as a Schottky barrier, for current blocking. Yet, an insulative layer formed between the flat surface regions of the p-type semiconductor layer and the transparent conductive layer also provides the current blocking effect. Accordingly, in operation, a current flow vertically from the p-type electrode to the flat surface regions of the p-type semiconductor layer is blocked, thereby, avoiding the current congestion effect under the flat surface regions, and increasing the light emitting efficiency of the LED.

Another advantage of the present invention is during the manufacture of the LED, desired portions of the light emitting area can selectively be flattened, such that the thickness of the transparent conductive layer over the flattened area/region is uniform. Comparing to the rough surface region, the transparent conductive layer over the additional flat surface regions has relative low resistance, and is used for paths of uniform current spreading. This enhances the current spreading ability of the LED 100D, thereby, further increasing the light emitting efficiency of the LED.

Although the embodiments of the present invention are described for horizontal type LEDs, one skilled in the art should appreciate that the present invention can also be applied to vertical type LEDs. For example, if the etching process is applied to only the region 118 to form a flat surface region thereon, and no flattening (e.g., etching) process is performed on the first semiconductor layer 102, a vertical type LED will be fabricated according to the processes of the present invention.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light emitting diode (LED), comprising:
a substrate;
a first semiconductor layer disposed on the substrate, having a first portion and a second portion extending from each other, wherein the first portion has a rough surface region and a flat surface region recessed relative to the rough surface region;
a light emitting layer disposed on the second portion of the first semiconductor layer, defining a light emitting region thereon;
a second semiconductor layer disposed on the light emitting layer, having a rough surface region and at least one flat surface region recessed relative to the rough surface region, wherein the first semiconductor layer and the second semiconductor layer have different electrical conductivities;
an insulative layer disposed on the at least flat surface region of the second semiconductor layer;
a transparent conductive layer disposed on the insulative layer and the rough surface region of the second semiconductor layer such that the transparent conductive layer has a rough surface region and a flat surface region corresponding to the rough surface region and the at least one flat surface region of the second semiconductor layer, respectively;
a first electrode disposed on the flat surface region of the first semiconductor layer; and
a second electrode disposed on the flat surface region of the transparent conductive layer.

2. The LED of claim 1, wherein the first semiconductor layer is formed of an n-type semiconductor, and the second semiconductor layer is formed of a p-type semiconductor, and wherein the first electrode is an n-type electrode, and the second electrode is a p-type electrode.

3. The LED of claim 1, wherein the insulative layer has a thickness greater than about 5 nm.

4. The LED of claim 1, wherein the insulative layer has an area greater than the at least one flat surface region of the second semiconductor layer.

5. The LED of claim 1, wherein the insulative layer comprises a multilayer having a reflective characteristic greater than about 50%.

6. The LED of claim 5, wherein the multilayer forms a distributed Bragg reflector (DBR).

7. The LED of claim 1, wherein the insulative layer is formed of SiO₂, SiN, TiO₂ or Al₂O₃.

8. The LED of claim 1, further comprising a passivation layer disposed on the rough surface region of the transparent conductive layer and the rough surface region of the first portion of the first semiconductor.

9. A light emitting diode (LED), comprising:
a substrate;
a first semiconductor layer disposed on the substrate;
a light emitting layer disposed on the first semiconductor layer;
a second semiconductor layer disposed on the light emitting layer, having a rough surface region and at least one flat surface region, wherein the first semiconductor layer and the second semiconductor layer have different electrical conductivities;
a transparent conductive layer disposed on the second semiconductor layer such that the transparent conductive layer has a rough surface region and a flat surface region corresponding to the rough surface region and the at least one flat surface region of the second semiconductor layer, respectively;
a first electrode electrically coupled to the first semiconductor layer; and
a second electrode disposed on the flat surface region of the transparent conductive layer,
wherein in operation, no current flows vertically from the flat surface region of the transparent conductive layer to the at least one flat surface region of the second semiconductor layer.

10. The LED of claim 9, wherein the first semiconductor layer has a first portion and a second portion extending from each other, wherein the first portion has a rough surface region and a flat surface region, wherein the first electrode disposed on the flat surface region of the first portion of the first semiconductor layer, and wherein the light emitting layer disposed on the second portion of the first semiconductor layer so as to define a light emitting region thereon.

11. The LED of claim 10, wherein the flat surface region of the first semiconductor layer is recessed relative to the rough surface region of the first semiconductor layer.

12. The LED of claim 10, wherein the first semiconductor layer is formed of an n-type semiconductor, and the second semiconductor layer is formed of a p-type semiconductor, and wherein the first electrode is an n-type electrode, and the second electrode is a p-type electrode.

13. The LED of claim 12, wherein the second semiconductor layer comprises:
a p-type semiconductor layer formed on the light emitting layer; and
a p+ doped semiconductor layer formed on the rough surface region of the p-type semiconductor layer.

14. The LED of claim 13, wherein the flat surface region of the transparent conductive layer and the at least one flat surface region of the second semiconductor layer are in a Schottky contact.

15. The LED of claim 9, further comprising a reflective layer formed between the flat surface region of the transparent conductive layer and the at least one flat surface region of the second semiconductor layer.

16. The LED of claim 15, wherein the reflective layer has an area greater than the at least one flat surface region of the second semiconductor layer.

17. The LED of claim 15, wherein the reflective layer comprises an insulative layer, a stacked structure of an insulative layer and a metal layer, or a metal layer.

18. The LED of claim 15, wherein the reflective layer comprises a single layer, or a multilayer.

19. The LED of claim 15, wherein the reflective layer comprises a distributed Bragg reflector (DBR).

20. The LED of claim 9, wherein the at least one flat surface region of the second semiconductor layer is recessed relative to the rough surface region of the second semiconductor layer.

21. The LED of claim 9, further comprising a passivation layer disposed on the rough surface region of the transparent conductive layer and the rough surface region of the first portion of the first semiconductor.

22. A method of manufacturing a light emitting diode (LED), comprising the steps of:
providing a substrate;
sequentially forming an n-type semiconductor layer on the substrate, a light emitting layer on the n-type semiconductor layer, and a p-type semiconductor layer on the light emitting layer, wherein the p-type semiconductor layer has a rough surface having a first region, a second region and a third region separated from the second region;
forming a first mask layer on the first region of the rough surface of the p-type semiconductor layer, thereby exposing the second and third regions of the rough surface of the p-type semiconductor layer;
forming a second mask layer on the first mask layer and the exposed second and third regions of the rough surface of the p-type semiconductor layer, wherein the second mask layer and the p-type semiconductor layer have a substantially same etching rate, wherein the first mask layer has an etching rate less than that of the second mask layer and the p-type semiconductor layer;
performing an etching process on the second mask layer and the first mask layer so as to form a first flat surface region and a second flat surface region in the second and third regions of the p-type semiconductor layer, respectively, and to expose the rough surface of the first region of the p-type semiconductor layer;
removing a portion of the p-type semiconductor layer in which the second flat surface region is located and a corresponding portion of the light emitting layer so as to expose a portion of the n-type semiconductor layer, and forming a third flat surface region on the exposed portion of the n-type semiconductor layer;
forming a transparent conductive layer on the rough surface region and the first flat surface region of the p-type semiconductor layer, such that the transparent conductive layer has a rough surface region and a flat surface region corresponding to the rough surface region and the first flat surface region of the p-type semiconductor layer, respectively; and
forming an n-type electrode on the third flat surface region of the n-type semiconductor layer and a p-type electrode on the flat surface region of transparent conductive layer.

23. The method of claim 22, wherein each of the n-type semiconductor layer, the light emitting layer and the p-type semiconductor layer is formed of a GaN based material.

24. The method of claim 22, wherein the first mask layer is formed of SiO₂, SiNx, SiOₓN_{y}, BPSG, spin-on-glass (SOG), or polyimide.

25. The method of claim 22, wherein the second mask layer is formed of a photoresist (PR) material.

26. The method of claim 22, wherein the second mask layer is formed of a spin-on-glass (SOG) material.

27. The method of claim 22, wherein the etching process is performed with a dry etching process.

28. The method of claim 27, wherein the dry etching process comprises an inductively coupled plasma (ICP) process, or a reactive ion etch (RIE) process.

29. The method of claim 22, wherein the p-type semiconductor layer comprises:
a p-type semiconductor layer formed on the light emitting layer; and
a p+ doped semiconductor layer formed on the p-type semiconductor layer.

30. The method of claim 29, wherein the etching process further comprises removing the p+ doped semiconductor layer in the second and third regions of the p-type semiconductor layer.

31. The method of claim 22, wherein the flat surface region of transparent conductive layer and the first flat surface region of the second semiconductor layer are in a Schottky contact.

32. The method of claim 22, further comprising the step of forming a reflective layer between the flat surface region of the transparent conduct layer and the first flat surface region of the p-type semiconductor layer.

33. The method of claim 22, wherein the third flat surface region on the exposed portion of the n-type semiconductor layer is corresponding to the second flat surface region of the p-type semiconductor layer, and wherein the exposed portion of the n-type semiconductor layer further has a rough surface region extending from the third flat surface region.

34. The method of claim 33, further comprising the step of forming a passivation layer on the rough surface region of the exposed portion of the n-type semiconductor layer and the rough surface region of the transparent conductive layer, after forming the n-type electrode and the p-type electrode.

35. The method of claim 22, wherein the p-type semiconductor layer has at least a fourth region extending from the second region, wherein the fourth region is adapted for forming a fourth flat surface region.
